(19) United States
(12) Patent Application Publication
(10) Pub. No.: US 2021/0325721 A1
(43) Pub. Date: Oct. 21, 2021

(54) DISPLAY PANEL AND MANUFACTURING METHOD THEREOF

(71) Applicant: WUHAN CHINA STAR OPTOELECTRONICS TECHNOLOGY CO., LTD., Wuhan, Hubei (CN)

(72) Inventor: Pengfei YU, Wuhan, Hubei (CN)

(73) Assignee: WUHAN CHINA STAR OPTOELECTRONICS TECHNOLOGY CO., LTD., Wuhan, Hubei (CN)

(21) Appl. No.: 16/621,923

(22) PCT Filed: Jun. 4, 2019
(86) PCT No.: PCT/CN2019/089948

§ 371 Date: Dec. 12, 2019

(30) Foreign Application Priority Data
May 16, 2019 (CN) 201910404859.1

(51) Int. Cl. G02F 1/1335

(52) U.S. Cl. CPC G02F 1/133512; G02F 1/133528; G02F 1/13685; G02F 2202/28; G02F 1/133567

(57) ABSTRACT

A display panel and a manufacturing method thereof are provided. The display panel includes an array substrate, a backlight, and an array substrate polarizer. The array substrate includes a plurality of thin-film transistors. The backlight is disposed under the array substrate and is configured to provide a light source. The array substrate polarizer is disposed on a surface of the array substrate facing the backlight, and includes a plurality of light-shielding portions corresponding to the thin-film transistors. The manufacturing method of the display panel includes steps of: forming an array substrate, forming an array substrate polarizer, bonding an array substrate polarizer, and bonding a backlight.

### FIELD OF INVENTION

The present application relates to a field of display technologies, and more particularly to a display panel and a manufacturing method thereof.

### BACKGROUND OF INVENTION

Currently, low temperature polysilicon (LTPS) array substrate products are composed of independent switching elements—thin-film transistors (TFTs), storage capacitors (Csts), and pixel transparent electrodes (or pixel electrodes). Semiconductor performance of the thin-film transistors is enhanced by ion implantation. Under electric field of scanning lines (gate), charging and discharging processes of the pixel transparent electrodes (or pixel electrode) are achieved. Voltage of a lower plate of the storage capacitors is adjusted to control rotation angles of liquid crystal molecules, thereby achieving colorful display effect of liquid crystal display products.

However, each of low temperature polysilicon array substrates of existing liquid crystal displays are provided with a light-shielding layer (LS) under the thin-film transistors. The light-shielding layer affects flatness of a surface under the channel section of the thin-film transistor semiconductors and cause the low temperature polysilicon array substrates cannot maintain a completely flat state.

Therefore, it is necessary to provide a new display panel and a manufacturing method thereof to overcome existing problems of prior art.

### Technical Problems

An object of the present disclosure is to provide a display panel and a manufacturing method thereof that removes light-shielding layers (LS) that are disposed on existing array substrate to maintain flatness under a surface of the semiconductor channel section of the thin-film transistors. Also, light-shielding layers are added on the polarizers corresponding to the thin-film transistors. After being attached on the polarizers of the liquid crystal display products, light-shielding layers are attached on outside of the polarizers to block the light source of the backlight, thereby protecting the semiconductor channel sections of the thin-film transistors from light. Cost of masks used by the light-shielding layer is saved and production cycle of the array substrate is shortened at the same time. Therefore, production cycle of the overall processes of the display panels are shortened.

### SUMMARY OF INVENTION

In order to solve the above problems, an embodiment of the present disclosure provides a display panel, comprising: an array substrate, a backlight, and an array substrate polarizer. Specifically, the array substrate comprises a plurality of thin-film transistors. The backlight disposed under the array substrate, wherein the backlight is configured to provide a light source. The array substrate polarizer disposed on a surface of the array substrate facing the backlight, wherein the array substrate polarizer comprises a plurality of light-shielding portions corresponding to the thin-film transistors.

Furthermore, the array substrate polarizer comprises: a polarizer body, wherein the light-shielding portions are disposed on a surface of the polarizer body away from the array substrate.

Furthermore, the array substrate polarizer comprises: a first adhesive layer and a second adhesive layer, wherein the first adhesive layer is configured to bond the polarizer body with the array substrate. The second adhesive layer is configured to bond the polarizer body with the backlight.

Furthermore, the array substrate comprises: a substrate layer, a buffer layer, and a driving circuit layer, wherein the substrate layer is disposed on a surface of the array substrate polarizer on which the light-shielding portions are disposed. The buffer layer is disposed on a surface of a side of the substrate layer. The driving circuit layer is disposed on a surface of the buffer layer away from the substrate layer. The thin-film transistors are disposed in the driving circuit layer.

Furthermore, each of the thin-film transistors comprises: an active layer, a gate insulating layer, a gate layer, an active layer, and an interlayer insulating layer that are laminated. The active layer is disposed on a surface of the array substrate polarizer on which the light-shielding portions are disposed. The gate insulating layer disposed on a surface of the gate layer away from the polarizer of the array substrate. The gate layer disposed on a surface of the gate insulating layer away from the active layer. The interlayer insulating layer disposed on a surface of the gate layer away from the gate insulating layer. The source and drain layer disposed on a surface of the interlayer insulating layer away from the gate layer.

Furthermore, the light-shielding portions correspond to the active layer.

Furthermore, the active layer comprises: a doped section and a semiconductor channel section. The light-shielding portions correspond to the semiconductor channel section.

Another embodiment of the present disclosure provides a manufacturing method of a display panel, comprising steps of:

forming an array substrate having a plurality of thin-film transistors;

providing an array substrate polarizer; bonding the array substrate polarizer with a lower surface of the array substrate; forming a plurality of light-shielding portions on a surface of the array substrate polarizer, wherein the light-shielding portions correspond to the thin-film transistors; and

assembling the backlight to the lower surface of the array substrate.

Furthermore, the array substrate polarizer comprises: a polarizer body, a first adhesive layer disposed on a surface of the polarizer body; and a second adhesive layer disposed on another surface of the polarizer body. The step of bonding the array substrate polarizer with the lower surface of the array substrate comprises: bonding the array substrate polarizer with the lower surface of the array substrate by the first adhesive layer. The step of assembling the backlight to the lower surface of the array substrate comprises: assembling the backlight to the lower surface of the array substrate by the second adhesive layer.

Furthermore, the step of forming the array substrate comprises steps of:

forming an active layer comprising a semiconductor channel section and a doped section;

forming a gate insulating layer on a surface of the active layer away from the array substrate polarizer;

forming a gate layer on a surface of the gate insulating layer away from the active layer and patterning the gate layer;

forming an interlayer insulating layer on a surface of the gate layer away from the gate insulating layer; and

forming a source and drain layer on a surface of the interlayer insulating layer away from the gate layer and patterning the source and drain layer;

wherein in the step of forming the light-shielding portions, the light-shielding portions are bonded with a surface of the array substrate polarizer away from the array substrate and the light-shielding portions correspond to the semiconductor channel section.

### Beneficial Effects

Beneficial effects of the present disclosure are to provide a display panel and a manufacturing method thereof that removes light-shielding layers (LS) that are disposed on existing array substrate to maintain flatness under a surface of the semiconductor channel section of the thin-film transistors. Also, light-shielding layers are added on the polarizers corresponding to the thin-film transistors. After being attached on the polarizers of the liquid crystal display products, light-shielding layers are attached on outside of the polarizers to block the light source of the backlight, thereby protecting the semiconductor channel sections of the thin-film transistors from light. Cost of masks used by the light-shielding layer is saved and production cycle of the array substrate is shortened at the same time. Therefore, production cycle of the overall processes of the display panels are shortened.

### DESCRIPTION OF DRAWINGS

FIG. 1 is a schematic structural view of a display panel according to an embodiment of the present disclosure.

FIG. 2 is a bottom view of a display panel according to an embodiment of the present disclosure.

FIG. 3 is a schematic structural view of a color filter substrate polarizer according to an embodiment of the invention.

FIG. 4 is a schematic structural diagram of a display panel according to another embodiment of the present disclosure.

FIG. 5 is a schematic structural diagram of the array substrate according to an embodiment of the present disclosure.

FIG. 6 is a flowchart of a manufacturing method of a display panel according to an embodiment of the present disclosure.

FIG. 7 is a flow chart of manufacturing thin-film transistors according to an embodiment of the present disclosure.

FIG. 8 is a flow chart of manufacturing the array substrate according to an embodiment of the present disclosure.

### REFERENCE NUMERALS IN DRAWINGS

1 an array substrate; 2 an array substrate polarizer; 3 a backlight; 4 a color filter substrate;
5 a liquid crystal layer; 6 a color filter substrate polarizer; 10 a thin-film transistor; 11 a semiconductor channel section;
12 a doped section; 20 a light-shielding portion; 21 a first through hole; 22 a second through hole;
31 a source; 32 a drain; 100 a display panel; 101 an active layer;
102 a gate insulating layer; 103 a gate layer; 104 an interlayer insulating layer; 105 a source and drain layer;
111 a substrate layer; 112 a buffer layer; 113 a driving circuit layer; 114 a planarization layer;
115 an anode layer; 116 a pixel defining layer; 201 a release paper; 202 a first adhesive layer;
203 a polarizer body; 204 a second adhesive layer; and 205 a protective film.

### DETAILED DESCRIPTION OF PREFERRED EMBODIMENTS

Preferred embodiments of the present disclosure are described in conjunction with the accompanying drawings to comprehensively introduce the technical schemes of the present disclosure to people with ordinary skills in the art and to demonstrate enablement of the present disclosure by exemplification. Therefore, those skilled in the art will more readily understand how to implement the present disclosure. The present disclosure may, however, be embodied in many different forms and embodiments and the scope of the present disclosure is not limited to the embodiments described herein.

Directional terminology mentioned in the present disclosure, such as “top”, “bottom”, “front”, “back”, “left”, “right”, “inner”, “outer”, “lateral”, etc., is used with reference to the orientation of the figures being described. The directional terms used in the drawings are used for purposes of illustration and is not intended to limit the scope of the present disclosure.

In the drawings, elements with identical structures are indicated by identical reference numbers, and elements with similar structure or function are denoted by similar reference numerals. Moreover, size and thickness of each component shown in the drawings are arbitrarily shown for ease of understanding and description. The present disclosure does not limit the size and thickness of each elements.

When an element is described as “disposed on” another element, the element can be placed directly on a surface of another element. There can also be an intermediate element. The element is placed on the intermediate element and the intermediate element is placed on another element. When an element is described as “installed to” or “connected to” another element, it can be directly understood as “install” or “connect” or an element is “installed to” or “connected to” another element via an intermediate element.

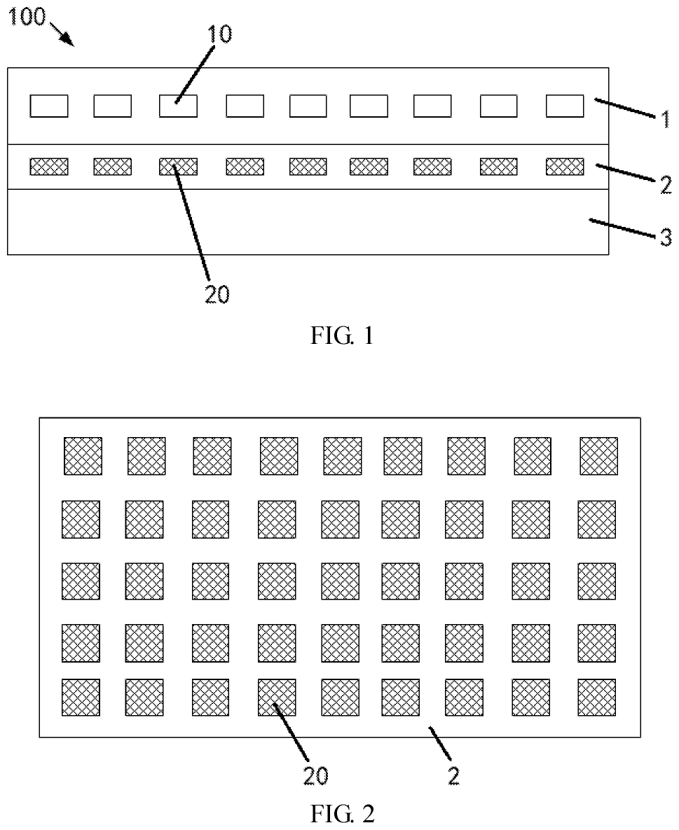

Please refer to FIG. 1 and FIG. 2. An embodiment of the present disclosure provides a display panel 100, including an array substrate 1, a backlight 3, and an array substrate polarizer 2 disposed therebetween. Specifically, the array substrate 1 has a plurality of thin-film transistors 10. The backlight 3 is disposed under the array substrate 1 to provide a light source. The array substrate polarizer 2 is disposed on a surface of the array substrate 1 facing the backlight 3. The array substrate polarizer 2 includes a plurality of light-shielding portions 20 corresponding to the thin-film transistors 10 for blocking light of the backlight 3 from entering the thin-film transistor 10. Therefore, the array substrate polarizer 2 is provided with the light-shielding portions 20 to block the light of the light source. The array substrate polarizer 2 can replace the light-shielding layer (LS) in the existing array substrate to protect the thin-film transistor 10 from being affected by the light.

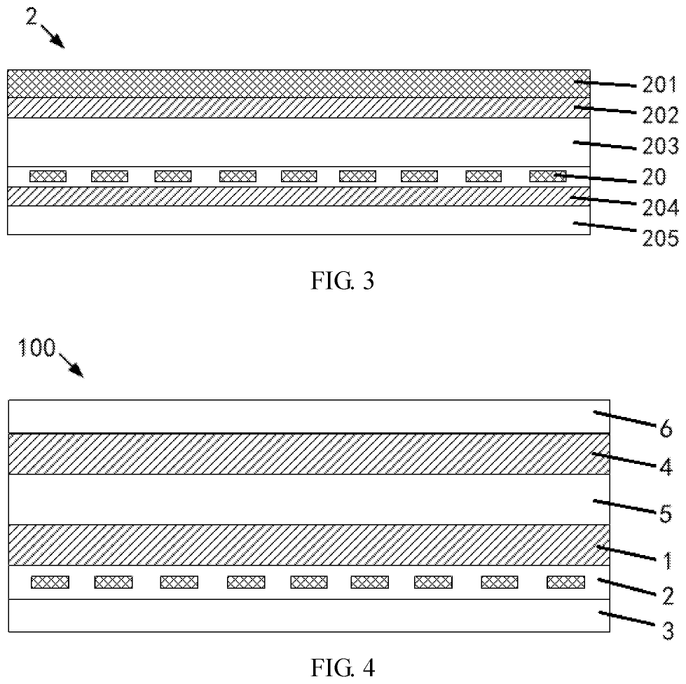

Please refer to FIG. 3. The array substrate polarizer 2 includes a polarizer body 203. The light-shielding portions 20 are formed on a surface of the polarizer body 203 away from the array substrate 1. The array substrate polarizer 2 further includes a first adhesive layer 202 and a second adhesive layer 204. The first adhesive layer 202 is configured to bond the polarizer body 203 with the array substrate 1. The second adhesive layer 204 is configured to bond the polarizer body 203 with the backlight 3. In order to maintain adhesion of the first adhesive layer 202 and the second adhesive layer 204, a release paper 202 is attached to the first adhesive layer 202 side and a protective film 205 is attached to one side of the second adhesive layer 204 before the array substrate polarizer 2 is used.

Please refer to FIG. 4. In other embodiments, the display panel 100 further includes a color filter substrate 4 and a liquid crystal layer 5. The color filter substrate 4 is disposed opposite to the array substrate 1 and the liquid crystal layer 5 between the array substrate 1 and the color filter substrate 4. The display panel 100 further includes a color filter substrate polarizer 6 disposed on a surface of the color filter substrate 4 away from the array substrate polarizer 2. The color filter substrate 4 includes a color filter. Polarizing position of the array substrate polarizer 2 and the color filter substrate 4 of the array substrate are disposed perpendicular to each other. A portion of parallel light is selectively entered into the liquid crystal cell 1 when the light passes through the array substrate polarizer 2. After being subject to 90 degrees of deflection by the liquid crystal layer 5, the parallel light can be emitted through the color filter substrate 4. Area of the array substrate 1 is the same as area of the color filter substrate 4, which is convenient to align the array substrate 1 and the color filter substrate 4.

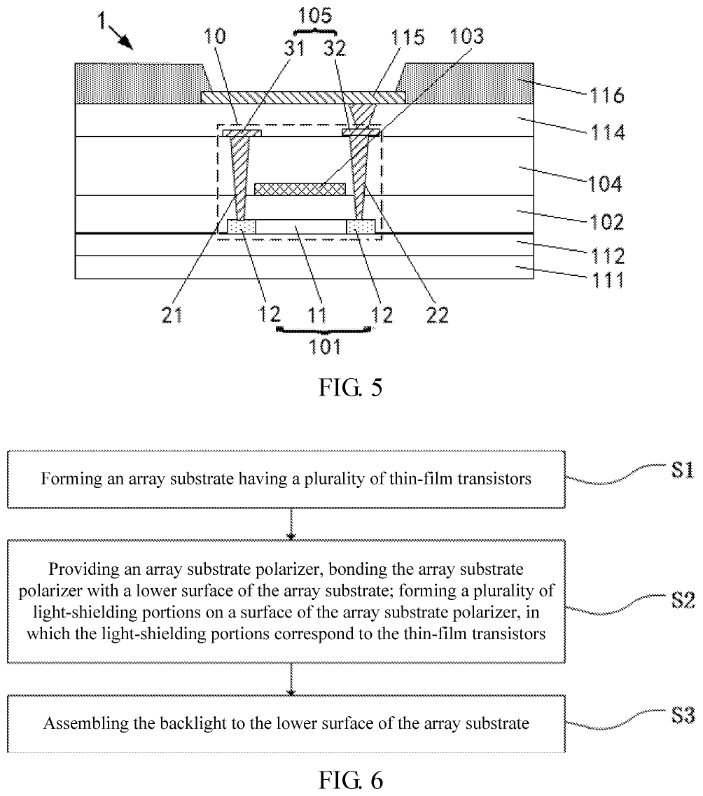

Please refer to FIG. 5. In the present embodiment, the array substrate 1 further includes a substrate layer 111, a buffer layer 112, and a driving circuit layer 113. Specifically, the substrate layer 11 is disposed on a surface of the array substrate polarizer 2 on which the light-shielding portions 20 are disposed. The buffer layer 112 is disposed on a surface of a side of the substrate layer 111. The driving circuit layer 113 is disposed on a surface of the buffer layer 112 away from the substrate layer 111. The thin-film transistor 10 is disposed on the driving circuit layer 113. Material of the substrate layer 111 comprises a flexible polyimide substrate. The buffer layer 112 comprises a single layer or a multi-layer structure. Material of the buffer layer 112 is generally SiOₓ, SiNₓ, or a mixture thereof. The substrate layer 111 or the buffer layer 112 is functional for buffering protection.

In the present embodiment, the array substrate 1 further includes a planarization layer 114, an anode layer 115, and a pixel defining layer 116. Specifically, the planarization layer 114 is disposed on a surface of the driving circuit layer 113 away from the substrate. The anode layer 115 is disposed on a surface of the planarization layer 114 away from a side of the driving circuit layer 113. The anode layer 115 is electrically connected to the driving circuit layer 113 for transmitting an electrical signal. The pixel defining layer 116 is disposed on a surface of a side of the anode layer 115 away from the planarization layer 114. An organic light emitting layer (not shown) is further disposed on the pixel defining layer 116. The organic light emitting layer is disposed opposite to the anode layer 115. The organic light emitting layer is connected to the anode layer 115 through the pixel defining layer 116, such that the organic light-emitting layer obtains an electrical signal for emitting light.

Please refer to FIG. 5. In the present embodiment, the thin-film transistor 10 includes an active layer 101, a gate insulating layer 102, a gate layer 103, an interlayer insulating layer 104, and a source and drain layer 105. Specifically, the active layer 101 is disposed on a side of the buffer layer 112 away from the substrate layer 111, i.e., on the surface of the array substrate polarizer 2 on which the light-shielding portions 20 are disposed. The gate insulating layer 102 is disposed on a surface of the active layer 101 away from the buffer layer 112, i.e., disposed on a surface of the gate layer 101 away from the polarizer 2 of the array substrate. The gate layer 103 is disposed on a surface of the insulating layer 102 away from the active layer 101. The interlayer insulating layer 104 is disposed on a surface of the gate layer 103 away from the gate insulating layer 102. The source and drain layer 105 is disposed on the interlayer insulating layer 104 away from the surface of the gate layer 103. The light-shielding portion 20 corresponds to the active layer 101 to protect the active layer 101 from being affected by light.

Please refer to FIG. 5. In the embodiment, the active layer 101 includes a doped section 12 and a semiconductor channel section 11. The light-shielding portions 20 corresponds to the semiconductor channel sections 11. More specifically, the source 31 is electrically connected to the source section of the doped section 12 via a first through hole 21. The drain 32 is electrically connected to the drain of the doped section 12 via a second through hole 22. The active layer 101 described above is used to form a low temperature polysilicon type array substrate. Material of the source and drain layer 105 includes a semiconductor. When the source and drain layer 105 are manufactured, both sides of the source and drain layer 105 are subject to a doping treatment to form the doped section 12. The section that is not doped is the semiconductor channel section 11. The semiconductor channel section 11 is used for forming an ion implantation channel. The light-shielding portion 20 corresponds to the semiconductor channel section 11 for shielding light, thereby protecting the semiconductor channel section 11 from being affected by light.

Please refer to FIG. 6 again. An embodiment of the present disclosure provides a manufacturing method of the display panel 100 including steps S1-S3 of,

a step S1 of forming an array substrate 1 having a plurality of thin-film transistors 10;

a step S2 of providing an array substrate polarizer 2, bonding the array substrate polarizer 2 with a lower surface of the array substrate 1; forming a plurality of light-shielding portions 20 on a surface of the array substrate polarizer 1, wherein the light-shielding portions 20 correspond to the thin-film transistors 10; and

a step S3 of assembling the backlight 3 to the lower surface of the array substrate 1.

The array substrate polarizer 2 includes a polarizer body 203, a first adhesive layer 202, and a second adhesive layer 204. The first adhesive layer 202 disposed on a surface of the polarizer body 203, and a second adhesive layer 204 disposed on another surface of the polarizer body. The step of bonding the array substrate polarizer 2 with the lower surface of the array substrate 1 includes bonding the array substrate polarizer 2 with the lower surface of the array substrate 1 by the first adhesive layer 202. The step of assembling the backlight 3 to the lower surface of the array substrate 1 includes assembling the backlight 3 to the lower surface of the array substrate 1 by the second adhesive layer 204.

In order to maintain adhesion of the first adhesive layer 202 and the second adhesive layer 204, a release paper 201 is attached on a side of the first adhesive layer 202. The surface of the polarizer body 203 that is disposed away from the release paper 201 includes a plurality of light-shielding portions 20. A protective film 205 is attached to a side of the second adhesive layer 204 to form the array substrate polarizer 2. The structure of the array substrate polarizer 2 is schematically shown in FIG. 3. The release paper 201 and the protective film 205 are torn off when the array substrate polarizer 2 is used.

The present disclosure maintains flatness of a surface under the semiconductor channel section 11 of the thin-film transistor 10 by removing the light-shielding layer (LS) of the existing array substrate. Also, the light-shielding portions 20 are added on the array substrate polarizer 2 corresponding to the thin-film transistor 10 to protect the thin-film transistor 10 from be affected by light and to save production cost and time.

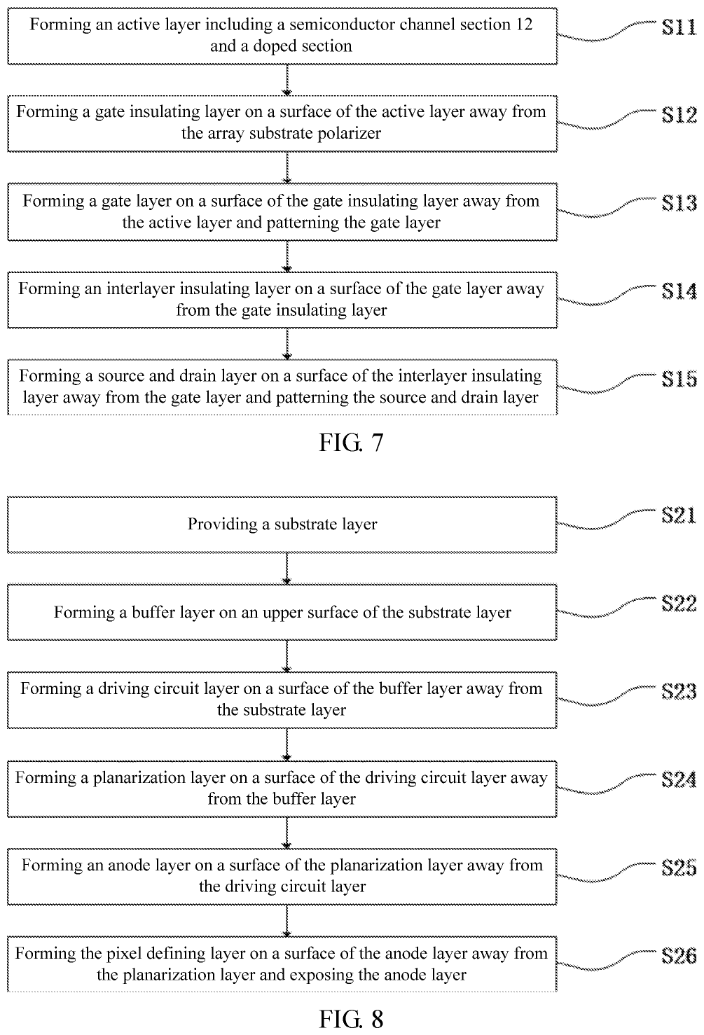

Please refer to FIG. 7. In the embodiment, the step of forming the thin-film transistor 10 of the array substrate 1 includes steps of,

a step S11 of forming an active layer 101 on an upper surface of the buffer layer 112, and doping the active layer 101 to form a semiconductor channel section 12 and a doped section 11 on the active layer 101.

A step S12 of forming a gate insulating layer 102 on a surface of the active layer 101 away from the array substrate polarizer 2.

A step S13 of forming a gate layer 103 on a surface of the gate insulating layer 102 away from the active layer 102 and patterning the gate layer 103.

A step S14 of forming an interlayer insulating layer 104 on a surface of the gate layer 103 away from the gate insulating layer 102, and defining a first through hole 21 and a second through hole 22 on an upper surface of the interlayer insulating layer 104. Bottom of the first through hole 21 is the source section of the doped section 11 and bottom of the second through hole 22 is the drain section of the doped section 11.

A step S15 of forming a source and drain layer 105 on a surface of the interlayer insulating layer 104 away from the gate layer 103 and patterning the source and drain layer 105, filling the first through hole 21 and the first The two through hole holes 22 with the source and drain layer 105, forming a source 31 at a position opposite to the first through hole 21, and forming a drain 32 at a position opposite to the second through hole 22.

In the step of forming the light-shielding portions 20, the light-shielding portions 20 are bonded with the surface of the array substrate polarizer 2 away from the array substrate 1. The light-shielding portion 20 corresponds to the semiconductor channel section 11 of the active layer 101 to protect the semiconductor channel section 11 from being affected by light.

Please refer to FIG. 8. In the embodiment, the step of forming the array substrate 1 includes steps S21-S26,

a step S21 of providing a substrate layer 111. Material of the substrate layer 111 is polyimide (PI) or other buffering material, which is functional for buffering protection.

A step S22 of forming a buffer layer 112 on an upper surface of the substrate layer 111. The buffer layer 112 includes a single layer or a multi-layer structure. Material of the buffer layer 112 is generally SiOₓ, SiNₓ, or a mixture thereof. The substrate layer 111 or the buffer layer 112 is functional for buffering protection.

A step S23 of forming a driving circuit layer 113 on a surface of the buffer layer 112 away from the substrate layer 111. The driving circuit layer 113 has a plurality of thin-film transistors 10.

A step S24 of forming a planarization layer 114 on a surface of the driving circuit layer 113 away from the buffer layer 112.

A step S25 of forming an anode layer 115 on a surface of the planarization layer 114 away from the driving circuit layer 113. The anode layer 115 is electrically connected to the source and drain layer 105 for transmitting electrical signals.

A step S26 of forming the pixel defining layer 116 on a surface of the anode layer 115 away from the planarization layer 114 and exposing the anode layer 115. An organic light emitting layer (not shown) is further disposed on the pixel defining layer 116. The organic light emitting layer is disposed opposite to the anode layer. The organic light emitting layer is connected to the anode layer through the pixel defining layer 116, such that the organic light-emitting layer obtains an electrical signal for emitting light.

Beneficial effects of the present disclosure are to provide a display panel and a manufacturing method thereof that removes light-shielding layers (LS) that are disposed on existing array substrate to maintain flatness under a surface of the semiconductor channel section of the thin-film transistors. Also, light-shielding layers are added on the polarizers corresponding to the thin-film transistors. After being attached on the polarizers of the liquid crystal display products, light-shielding layers are attached on outside of the polarizers to block the light source of the backlight, thereby protecting the semiconductor channel sections of the thin-film transistors from light. Cost of masks used by the light-shielding layer is saved and production cycle of the array substrate is shortened at the same time. Therefore, production cycle of the overall processes of the display panels are shortened.

The above are merely the preferred embodiments of the present disclosure. It should be appreciated that a person skilled in the art may further make modifications and improvements without departing from the principle of the present disclosure, and these modifications and improvements shall also fall within the scope of the present disclosure.

1. A display panel, comprising:
an array substrate comprising a plurality of thin-film transistors;
a backlight disposed under the array substrate, wherein the backlight is configured to provide a light source; and
an array substrate polarizer disposed on a surface of the array substrate facing the backlight, wherein the array substrate polarizer comprises a plurality of light-shielding portions corresponding to the thin-film transistors.

2. The display panel according to claim 1, wherein the array substrate polarizer comprises:
a polarizer body, wherein the light-shielding portions are disposed on a surface of the polarizer body away from the array substrate.

3. The display panel according to claim 1, wherein the array substrate polarizer comprises:
a first adhesive layer, wherein the first adhesive layer is configured to bond the polarizer body with the array substrate; and
a second adhesive layer, wherein the second adhesive layer is configured to bond the polarizer body with the backlight.

4. The display panel according to claim 1, wherein the array substrate comprises:
a substrate layer disposed on a surface of the array substrate polarizer on which the light-shielding portions are disposed;
a buffer layer disposed on a surface of a side of the substrate layer; and
a driving circuit layer disposed on a surface of the buffer layer away from the substrate layer, wherein the thin-film transistors are disposed in the driving circuit layer.

5. The display panel according to claim 1, wherein each of the thin-film transistors comprises:
an active layer disposed on a surface of the array substrate polarizer on which the light-shielding portions are disposed;
a gate insulating layer disposed on a surface of the gate layer away from the polarizer of the array substrate;
a gate layer disposed on a surface of the gate insulating layer away from the active layer;
an interlayer insulating layer disposed on a surface of the gate layer away from the gate insulating layer; and
a source and drain layer disposed on a surface of the interlayer insulating layer away from the gate layer.

6. The display panel according to claim 5, wherein the light-shielding portions correspond to the active layer.

7. The display panel according to claim 5, wherein the active layer comprises:
a doped section; and
a semiconductor channel section;
wherein the light-shielding portions correspond to the semiconductor channel section.

8. A manufacturing method of a display panel, comprising steps of:
forming an array substrate having a plurality of thin-film transistors;
providing an array substrate polarizer; bonding the array substrate polarizer with a lower surface of the array substrate; forming a plurality of light-shielding portions on a surface of the array substrate polarizer, wherein the light-shielding portions correspond to the thin-film transistors; and
assembling a backlight to the lower surface of the array substrate.

9. The manufacturing method of a display panel according to claim 8,
wherein the array substrate polarizer comprises:
a polarizer body,
a first adhesive layer disposed on a surface of the polarizer body; and
a second adhesive layer disposed on another surface of the polarizer body;
wherein the step of bonding the array substrate polarizer with the lower surface of the array substrate comprises: bonding the array substrate polarizer with the lower surface of the array substrate by the first adhesive layer; and wherein the step of assembling the backlight to the lower surface of the array substrate comprises: assembling the backlight to the lower surface of the array substrate by the second adhesive layer.

10. The manufacturing method of the display panel according to claim 8,
wherein the step of forming the array substrate comprises steps of:
forming an active layer comprising a semiconductor channel section and a doped section;
forming a gate insulating layer on a surface of the active layer away from the array substrate polarizer;
forming a gate layer on a surface of the gate insulating layer away from the active layer and patterning the gate layer;
forming an interlayer insulating layer on a surface of the gate layer away from the gate insulating layer; and
forming a source and drain layer on a surface of the interlayer insulating layer away from the gate layer and patterning the source and drain layer;
wherein in the step of forming the light-shielding portions, the light-shielding portions are bonded with the surface of the array substrate polarizer away from the array substrate and the light-shielding portions correspond to the semiconductor channel section.
